(19) United States
(12) Patent Application Publication
(10) Pub. No.: US 2003/0191882 A1
(43) Pub. Date: Oct. 9, 2003

(54) Integrated multi-function storing means

(76) Inventor: Calvin Chang, Miao-Lih Hsuan (TW)

Correspondence Address: PERKINS COIE LLP, PATENT-SEA, P.O. BOX 1247, SEATTLE, WA, 98111-1247, US

(21) Appl. No.: 10/138,354

(22) Filed: May 3, 2002

(30) Foreign Application Priority Data
Apr. 4, 2002 (TW) 091204418

(51) Int. Cl. H05K 7/10

(52) U.S. Cl. 710/301

(57) ABSTRACT

An integrated multi-function storing means, comprising: a multi-storage connecting interface for connecting each kind of storage medium device, a user may alter each storage medium device. A multi-function card reader is used for achieving the function of reading pluralities of memory cards. A universal serial bus (USB) IS connected to the multi-storage connecting interface and the multi-function card reader for data transmission. A HUB connected to the USB includes a plurality of connecting ports for connecting at least two computer peripheral devices. Control circuits are connected to the HUB for driving the corresponding device.

This application is a cross-reference application of an application, Ser. No. ______, filed by the identical assignee on Apr. 30, 2002 entitled, “CARD READER SYSTEM FOR INSTALLED IN A PERSONAL COMPUTER.”

### FIELD OF THE INVENTION

The present invention relates to means for storing data or information, and more specifically, to a multi-function storing means for computer system.

### BACKGROUND OF THE INVENTION

In recent years, the computer and Internet technique are dramatically developed with a brisk step due to the improvement of the semiconductor industry, the computer and the communication techniques. The various of cards are popular in these years, such as credit card, bank card, ID card and so on. The memory card is also widely used due to the improvement of the semiconductor technology. Card reader is one of the means for reading the information stored in the card. The card reader has a connector that is connected to the ICs. Based on the report, the memory card user population is dramatically increasing all of the world. More recently, a memory card or a smart card having an integrated circuit (IC) memory chip has been developed with increased capability of storing data, which can hold much more information than a magnetic strip type card. Use of the memory cards is rapidly increasing in the banking industry and for the purpose of storing personal data, such as electronic identification cards, driver's licenses, social security cards, financial cards and others.

Pluralities of storage medium types have been developed to fit each kind of storage medium. Thus, in order to fetch the information of the storage medium, the user has to prepare each individual card reader to read the different format data. Apparently, the cost is high and it is unlikely for the user to carry all of the card readers with oneself. To access the information stored on the memory card, the card reader should be equipped with a connector making an electrical connection with the contact elements of the semiconductor device, e.g. the IC chip.

The card reader typically includes a microprocessor to control the input/output and the transmission protocol. The major fact for the price of the card reader mainly depends on microprocessor. The current developed memory or smart card has better performance than ever, they can capacity more data than the magnetic strip type card. The computer peripheral devices are popular and the Internet provides the user a multi-medium environment. Therefore, the card reader and the storage medium are required for the user to fetch the information. However, up to now, it is unlikely for the user to connect and access the each kind of the storage means at the same time. Namely, while the user uses the A device, the B device is incapable for being process. The user has to separates the A device and connects the B device. After that, the user may drive the device B. It is not convenient for the user.

What is need is to integrate the pluralities of card reader or the like.

### SUMMARY OF THE INVENTION

An object of the present invention is to provide a multi-function storing means having a plurality of storage medium that may be integrated therein.

An integrated multi-function storing means, comprising: a multi-storage connecting interface for connecting each kind of storage medium device, a user may alter each storage medium device. A multi-function card reader is used for achieving the function of reading pluralities of memory cards. A universal serial bus (USB) IS connected to the multi-storage connecting interface and the multi-function card reader for data transmission. A HUB connection to the USB includes a plurality of connecting ports for connecting at least two computer peripheral devices. Control circuits are connected to the HUB for driving the corresponding device.

Wherein a compatible card reader unit in the multi-function card reader includes, but not limited to, C.F., S.D/MMC, memory card, smart card and digital camera memory card. Wherein a compatible storage medium device includes, but not limited to, CD-RW, DVD-RW, MO hard driver, ZIP, SVCD, MP3, CD-R, VCD, FLASH memory.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a functional diagram of the present invention.

### DETAILED DESCRIPTION OF THE PREFERRED EMBODIMENT

Some sample embodiments of the invention will now be described in greater detail. Nevertheless, it should be noted that the present invention can be practiced in a wide range of other embodiments besides those explicitly described, and the scope of the present invention is expressly not limited except as specified in the accompanying claims.

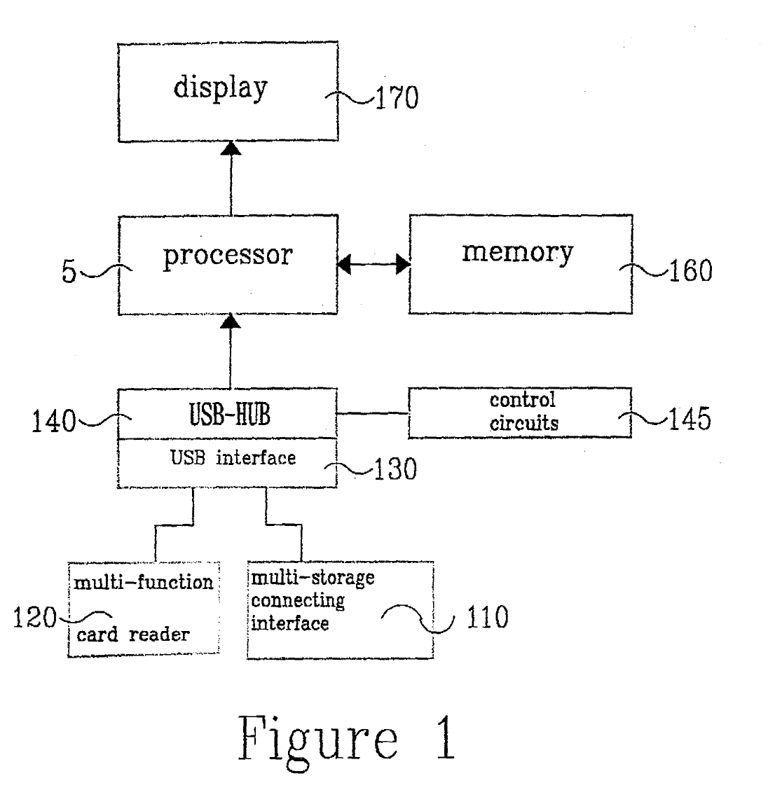

The present invention discloses storing means having pluralities of storage medium integrated therein. The present invention integrates at least two different card readers and/or storage medium. With reference to the figure, FIG. 1 illustrates a functional block diagram for the present invention. The apparatus includes a multi-storage connecting interface 110. The interface may connect each kind of the storage medium device. The user may alter each storage medium device. The compatible storage medium device includes, but not limited to, CD-RW, DVD-RW, MO, hard driver, ZIP, SVCD, MP3, CD-R, VCD, FLASH memory.

A multi-function card reader 120 is constructed by pluralities of card reader unit. The detailed description of the multi-function card reader 120 may refer to the co-pending application filed by the identical assignee. The Application number is ______. Each of the card reader units contains a plurality of connectors, the plurality of card reader units electrical connects with the personal computer by using a transmission interface. After the inserting of the memory cards into the connectors, the memory cards data is read. The card reader unit may be stacked by at least two connectors. This type may scale the size of the apparatus and enable pluralities memory card to be operated for achieving the function of reading pluralities of memory cards. The card reader unit includes connectors and connected to the computer by using interface. The other connector in the card reader unit may connect to the computer peripheral device. The compatible card reader unit in the multi-function card reader 120 includes, but not limited to, C.F., S.D/MMC, memory card, smart card and digital camera memory card.

A universal serial bus (USB) 130 is coupled to the multi-storage connecting interface 110 and the multi-function card reader 120 for data transmission. A HUB 140 is connected to the USB 130 and the HUB 140 includes a plurality of connecting ports for connecting at least two computer peripheral devices. Each connecting ports of the HUB 140 connect to a control circuits 145 for driving the corresponding device. Pluralities of media attached unit are respectively connected to the corresponding control circuits 145.

A processor 150 is connected to the HUB 140 for processing the data. Memory 160 is used to store the operation system, program and other software. A monitor 170 is connected to the processor 150 for displaying.

The present invention may provide multi-function connection, and is capable for reading different format memory card and further reading each storage medium.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. Thus, while the preferred embodiment of the invention has been illustrated and described, it will be appreciated that various changes can be made therein without departing from the spirit and scope of the invention.

The embodiments of the invention in which an exclusive property or privilege is claimed are defined as follows:

I/We claim:

1. An integrated multi-function storing means, comprising:
a multi-storage connecting interface for connecting each kind of storage medium device, a user may alter each storage medium device;
a multi-function card reader for achieving the function of reading pluralities of memory cards;
a universal serial bus (USB) connected to said multi-storage connecting interface and said multi-function card reader for data transmission;
a HUB connected to said USB includes a plurality of connecting ports for connecting at least two computer peripheral devices; and
control circuits connected to said HUB for driving the corresponding device.

2. The means of claim 1, wherein a processor is connected to said HUB for processing the data, a memory used to store the operation system, program and other software, a monitor connected to said processor for displaying.

3. The means of claim 1, wherein a compatible card reader unit in said multi-function card reader includes, but not limited to, C.F., S.D/MMC, memory card, smart card and digital camera memory card.

4. The means of claim 1, wherein, wherein a compatible storage medium device includes, but not limited to, CD-RW, DVD-RW, MO, hard driver, ZIP, SVCD, MP3, CD-R, VCD, FLASH memory.
